(19) United States
(12) Patent Application Publication
(10) Pub. No.: US 2013/0146962 A1
(43) Pub. Date: Jun. 13, 2013

(54) SEMICONDUCTOR DEVICE AND METHOD OF MANUFACTURING THE SAME

(71) Applicants: Jung Ryul AHN, Gyeonggi-do (KR); Yun Kyoung Lee, Seoul (KR)

(72) Inventors: Jung Ryul AHN, Gyeonggi-do (KR); Yun Kyoung Lee, Seoul (KR)

(21) Appl. No.: 13/598,942

(22) Filed: Aug. 30, 2012

(30) Foreign Application Priority Data
Dec. 13, 2011 (KR) 10-2011-0133716

(51) Int. Cl. H01L 29/788; H01L 21/336

(52) U.S. Cl. 257/316; 438/259; 257/E29.3; 257/E21.422

(57) ABSTRACT

A semiconductor device includes a plurality of first trenches having a first depth formed in a semiconductor substrate, a plurality of second trenches having a second depth formed in the semiconductor substrate, wherein the second depth is different from the first depth and the second trenches are formed between the first trenches, a plurality of isolation layers formed at the plurality of first trenches and the plurality of second trenches, wherein the isolation layers have upper portions formed above the semiconductor substrate, and a plurality of memory cells formed over the semiconductor substrate between the isolation layers.

### CROSS-REFERENCE TO RELATED APPLICATION

Priority is claimed to Korean patent application number 10-2011-0133716 filed on Dec. 13, 2011, the entire disclosure of which is incorporated herein by reference in its entirety.

### BACKGROUND

1. Field of Invention

Embodiments of the present invention relate to a semiconductor device and a method of manufacturing the same and, to a semiconductor device including an isolation region and a method of manufacturing the same.

2. Description of Related Art

To achieve higher integration degrees of semiconductor devices, a pattern width and spacing between adjacent patterns should decrease. The pattern width and the spacing between patterns are determined based on a resolution of exposure equipment. A decrease in the pattern width and the spacing between patterns may have limitations due to a limit on the resolution of exposure equipment.

For these reasons, higher integration degrees of semiconductor devices may not be achieved without increasing the resolution of the exposure equipment.

### BRIEF SUMMARY

Exemplary embodiments of the present invention relate to forming fine patterns with a pattern width smaller than a resolution of exposure equipment and at the same time, separating patterns from one another by a shorter distance.

A semiconductor device according to an exemplary embodiment of the present invention includes a plurality of first trenches having a first depth formed in a semiconductor substrate, a plurality of second trenches having a second depth formed in the semiconductor substrate, wherein the second depth is different from the first depth and the second trenches are formed between the first trenches, a plurality of isolation layers formed at the plurality of first trenches and the plurality of second trenches, wherein the isolation layers have upper portions formed above the semiconductor substrate, and a plurality of memory cells formed over the semiconductor substrate between the isolation layers.

A method of manufacturing a semiconductor device according to an exemplary embodiment of the present invention includes forming a plurality of first trenches having a first depth by etching a semiconductor substrate, forming a plurality of first isolation layers at first trenches, wherein the first isolation layers have upper portions formed above the semiconductor substrate, forming second trenches having a second depth different from the first depth by removing the semiconductor substrate between the first isolation layers, forming a plurality of second isolation layers at the plurality of second trenches, wherein the second isolation layers have upper portions above the semiconductor substrate, and forming a plurality of memory cells over the semiconductor substrate between the first and second isolation layers.

### BRIEF DESCRIPTION OF THE DRAWINGS

FIGS. 1A to 1J are views illustrating a method of manufacturing a semiconductor device according to an embodiment of the present invention;

FIG. 2 is a cross-sectional view illustrating operations of a semiconductor device according to an embodiment of the present invention; and

FIG. 3 is a cross-sectional view illustrating the structure of a semiconductor device according to another embodiment of the present invention.

### DESCRIPTION OF EMBODIMENTS

Hereinafter, various embodiments of the present disclosure will be described in detail with reference to the accompanying drawings. The figures are provided to enable those of ordinary skill in the art to make and use the present invention according to the exemplary embodiments of the present invention.

It should be readily understood that the meaning of “on” and “over” in the present disclosure should be interpreted in the broadest manner such that “on” not only means “directly on” something but also include the meaning of “on” something with an intermediate feature or a layer therebetween, and that “over” not only means the meaning of “over” something may also include the meaning it is “over” something with no intermediate feature or layer therebetween (i.e., directly on something).

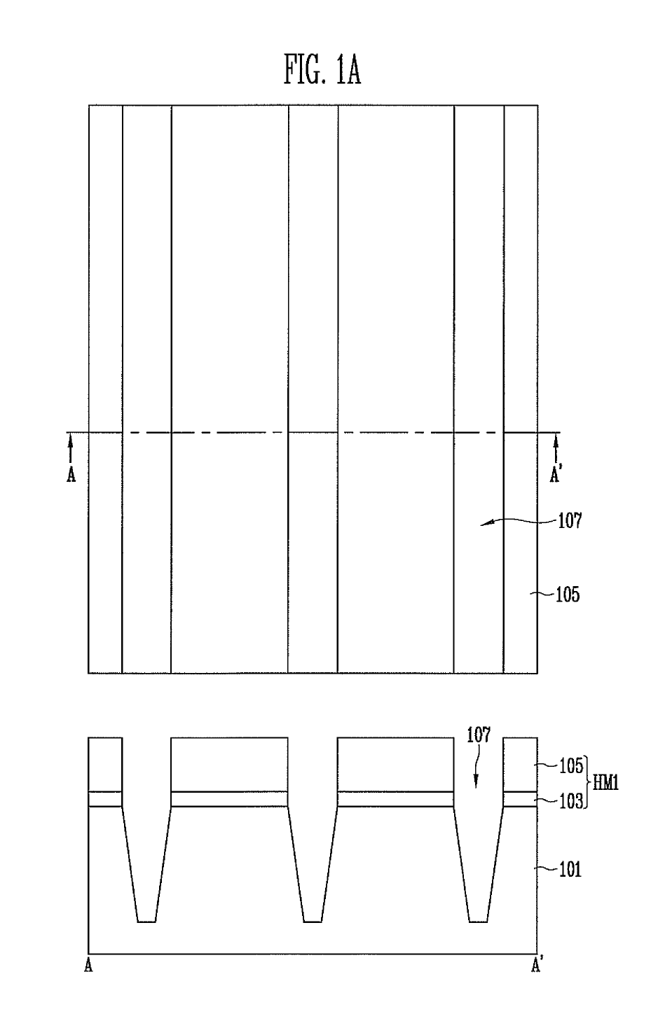

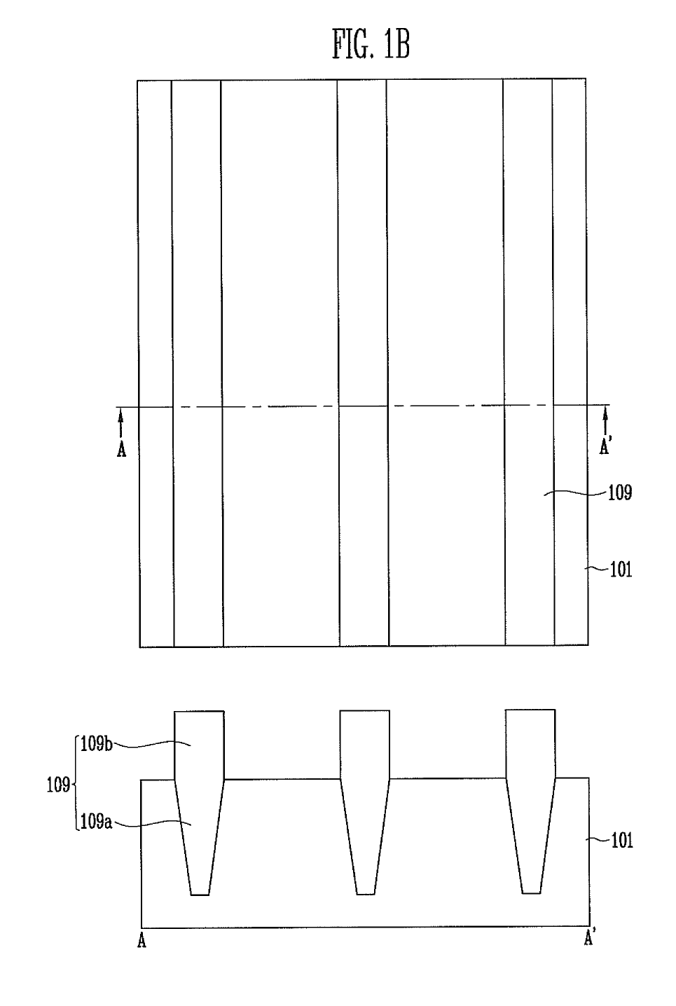

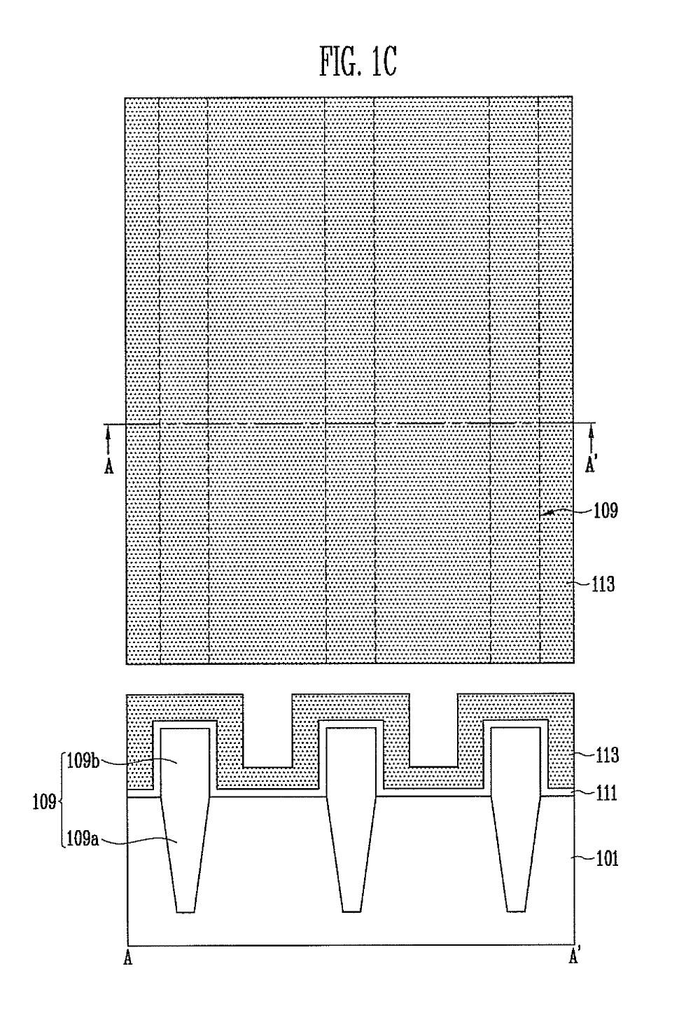

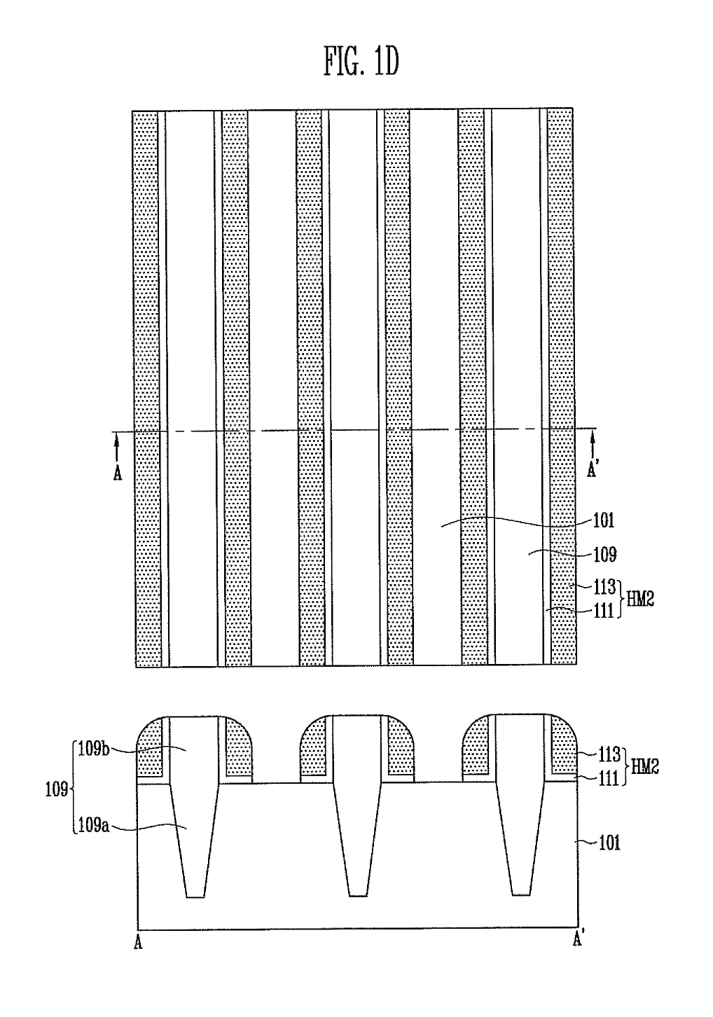

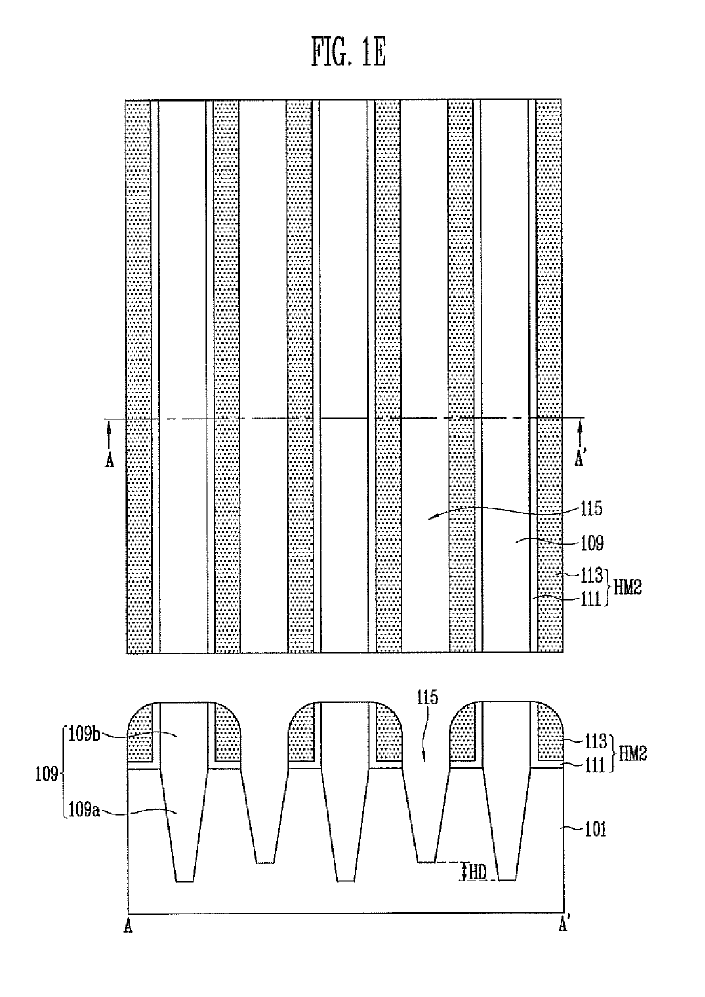

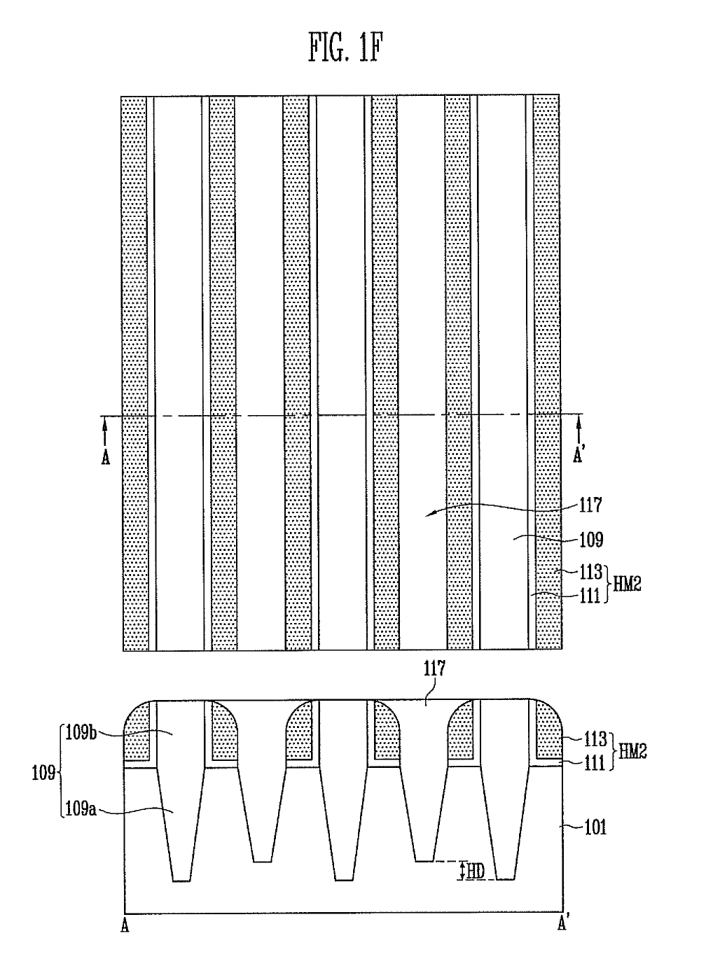

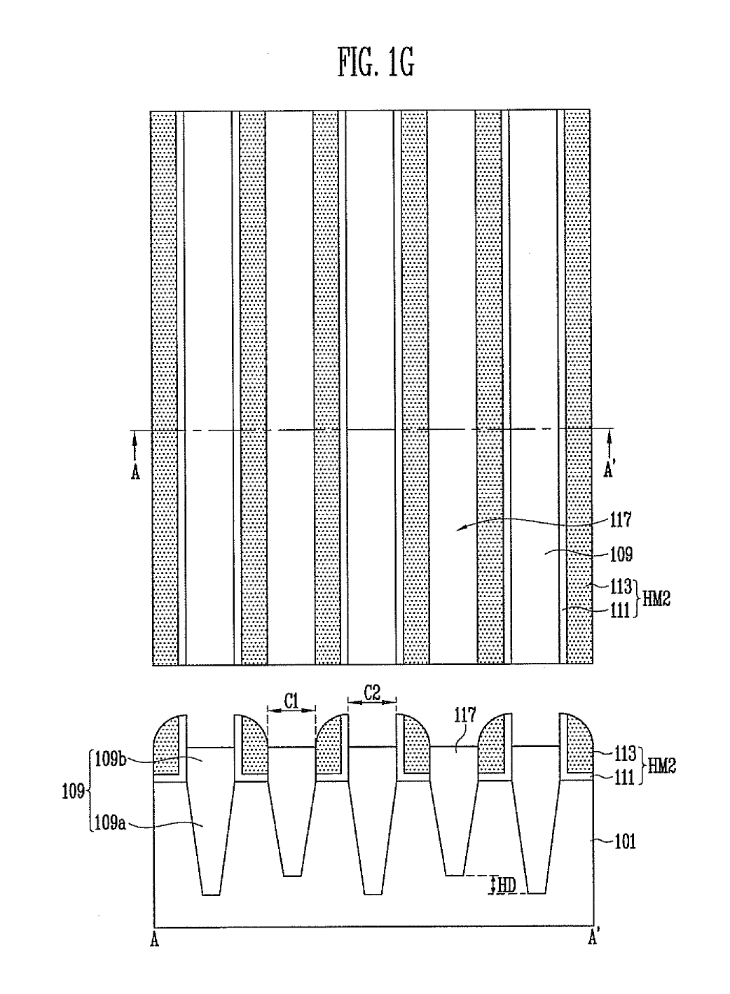

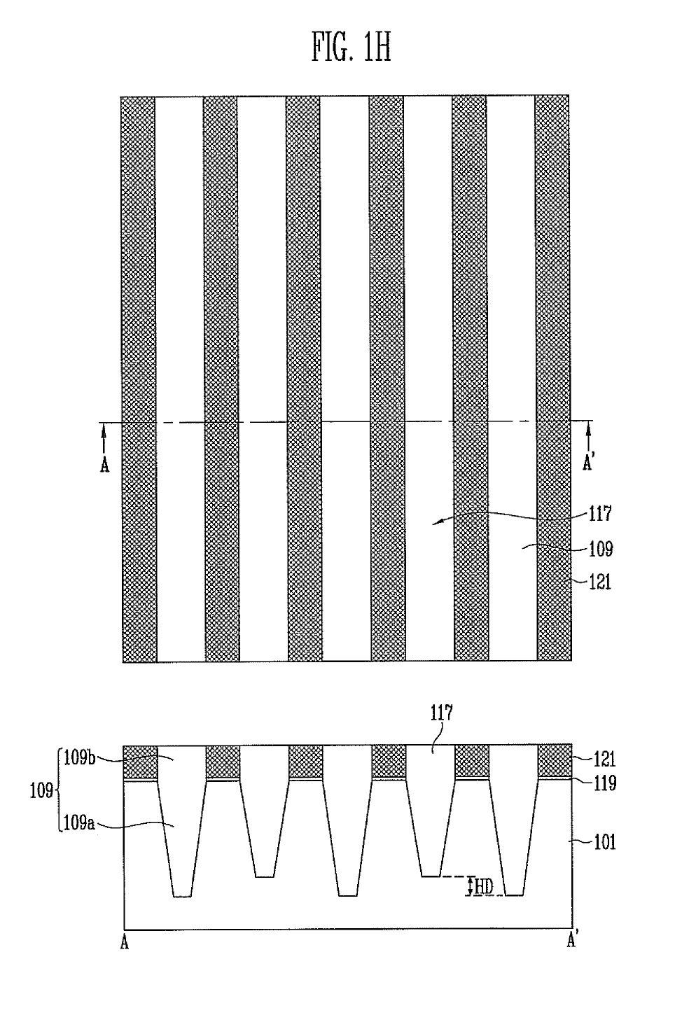

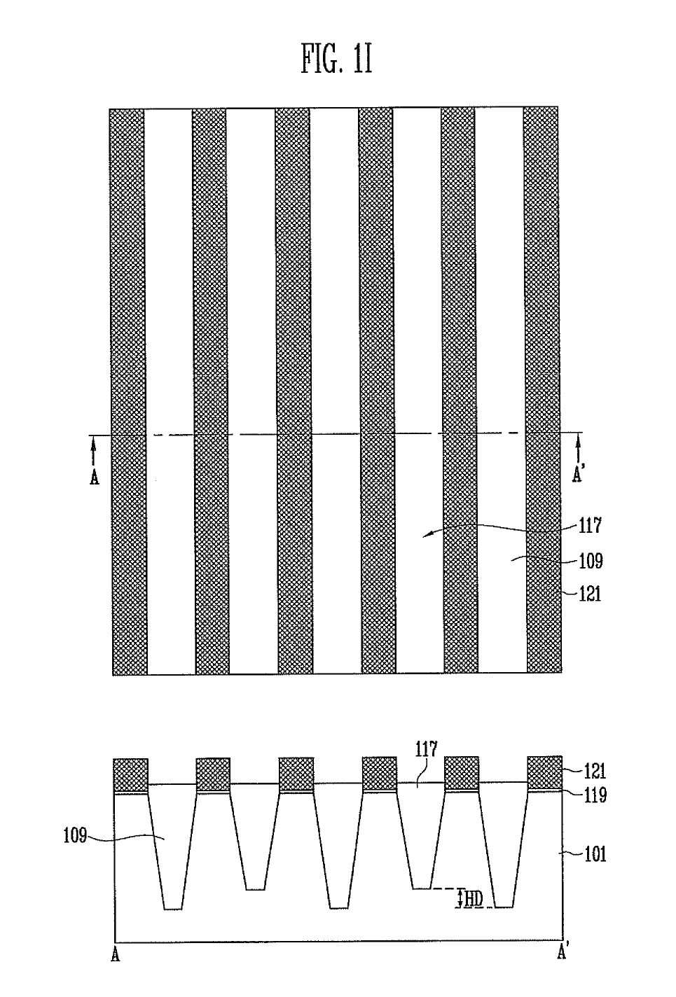

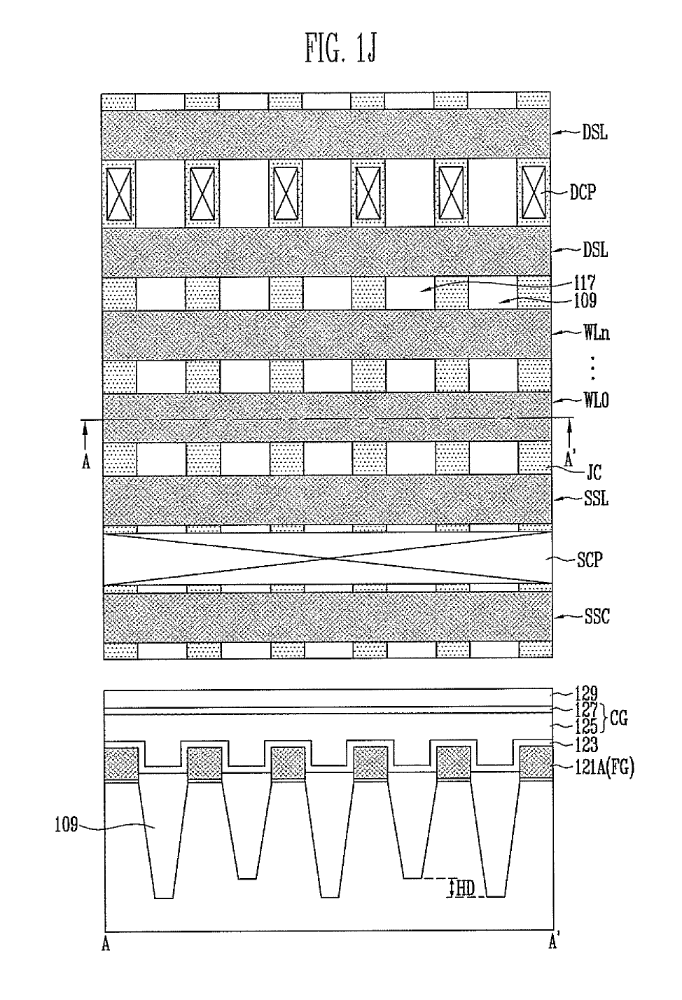

FIGS. 1A to 13 are views illustrating a method of manufacturing a semiconductor device according to an embodiment of the present invention.

Referring to FIG. 1A, a hard mask pattern HM1 may be formed on a semiconductor substrate 101 so that the hard mask pattern HM1 may expose isolation regions. The hard mask pattern HM1 may have a stacked structure of an oxide layer 103 and a nitride layer 105. In a cell region, the hard mask pattern HM1 may expose the isolation regions in a shape of parallel lines.

More specifically, the oxide layer 103 and the nitride layer 105 may be sequentially formed over the semiconductor substrate 101. The nitride layer 105 may be coated with a photoresist, and exposure and development processes may be performed to form a photoresist pattern (not illustrated). The photoresist pattern may expose portions of the semiconductor substrate 101 where odd or even isolation regions are to be formed. The exposed portions may have linear shapes arranged side by side, e.g., the exposed portions may be parallel to each other.

The photoresist pattern may expose the portions of the semiconductor substrate 101 so that the even or odd isolation regions may be separated by the minimum space that may be defined by a resolution of exposure equipment. The nitride layer 105 and the oxide layer 103 may be sequentially etched by an etch process using the photoresist pattern as an etch mask to form the hard mask pattern HM1. After the photoresist pattern is removed, the semiconductor substrate 101 may be etched by an etch process that uses the hard mask pattern HM1 as an etch mask to form trenches 107.

Referring to FIG. 1B, an insulating layer may be formed over an entire structure to fill the trenches 107. Subsequently, the insulating layer on the hard mask pattern HM1 may be removed to form first isolation layers 109 at regions where the trenches 107 are formed. An oxidation process may be performed before the insulating layer is formed so that an oxide layer (not illustrated) may be formed along an inner wall of each trench. Subsequently, the hard mask pattern HM1 may be removed. As a result, upper portions of the first isolation layers 109b may be formed at higher positions than the semiconductor substrate 101 by a thickness of the hard mask pattern HM1. Lower portions of the first isolation layers 109a may be formed in the semiconductor substrate 101 by a depth of each trench 107.

Referring to FIG. 1C, processes of forming hard mask spacers HM2 on sidewalls of the upper portions of the isolation layers 109b may be performed.

First, an oxide layer 111 and a nitride layer 113 may be sequentially formed over an entire structure including the sidewalls of the upper portions of the isolation layers 109b. Here, a total thickness of the oxide layer 111 and the nitride layer 113 may be large enough to maintain a difference in level caused by the upper portions of the isolation layers 109b.

Referring to FIG. 1D, a blanket etch process may be performed so that the oxide layer 111 and the nitride layer 113 may remain on the sidewalls of the upper portions of the isolation layers 109.

A horizontal thickness of each of the hard mask spacers HM2 on the sidewalls of the isolation layers 109 may determine a width of a portion of the semiconductor substrate 101 that is exposed between adjacent hard mask spacers HM2. The exposed portion of the semiconductor substrate 101 may be another isolation region. Therefore, the horizontal thickness of each of the hard mask spacers HM2 on the sidewalls of the isolation layers 109 may determine a width of another isolation region. In addition, portions of the semiconductor substrate 101 where the hard mask spacers HM2 are formed may be defined as active regions. Therefore, a width of the active region may be determined by the horizontal thickness of the hard mask spacer HM2.

Referring to 1E, the semiconductor substrate 101 between the hard mask spacers HM2 may be removed by an etch process that uses the hard mask spacers HM2 as an etch mask to form trenches 115. Here, each of the trenches 115 may have a different depth from each of the trenches 107 described above with reference to FIG. 1A. For example, each of the trenches 115 may be shallower than each of the trenches 107 as illustrated in FIG. 1E. As a result, there may be a depth difference HD between the trench 115 and the trench 107. The reason why the trenches 115 and the trenches 107 have different depths is described below.

Referring to FIG. 1F, an insulating layer may be formed over an entire structure to fill the trenches 115. Subsequently, a planarization process such as chemical mechanical polishing may be performed until the hard mask spacers HM2 are exposed, so that second isolation layers 117 may be formed at regions where the trenches 115 are formed. Before the insulating layer is formed, an oxidation process may be performed to form an oxide layer (not illustrated) along an inner wall surface of each trench. The upper portion of each second isolation layer 117 may be formed at a higher position than the semiconductor substrate 101 by a height of each hard mask spacer HM2. As a result, each of the second isolation layers 117 may be arranged between adjacent first isolation layers 109.

Through the aforementioned processes, a distance between adjacent isolation layers 109 and 117 may be controlled to be smaller than the minimum space that may be defined by a resolution of exposure equipment through a single exposure and development process.

Referring to 1G, the upper portions of the isolation layers 109 and 117 may be etched to expose upper sidewalls of the hard mask spacers HM2. Here, a thickness that the upper portion of each of the isolation layers 109 and 117 is etched may be controlled to prevent an exposure of an edge of the insulating layer 111. Amounts of the upper portions of the isolation layers 109 and 117 that are etched may be controlled so that widths C1 and C2 of the remaining isolation layers 117 and 109, respectively, may be substantially the same as each other.

Referring to FIG. 1H, the hard mask spacers HM2 may be removed. Subsequently, insulating layers 119 and silicon layers 121 may be formed over the semiconductor substrate 101 between the isolation layers 109 and 117. For example, the insulating layers 119 may be configured to be used as tunnel insulating layers, and the silicon layers 121 may be configured to be used as charge storage layers or floating gates.

More specifically, the semiconductor substrate 101 between the isolation layers 109 and 117 may be oxidized to form tunnel insulating layers 119. Here, the tunnel insulating layers 119 may include conductive dots formed of, for example, ruthenium (Ru), silicon (Si), titanium (Ti) or platinum (Pt). Because a method of forming a layer that includes conductive dots is known in the field of invention, a detailed description of this method will be omitted.

Subsequently, a silicon layer may be formed over an entire structure so that the silicon layer may be filled between the upper portions of the isolation layers 109 and 117. After that, a polishing process may be performed until top surfaces of the isolation layers 109 and 117 are exposed. As a result, the insulating layers 119 and the silicon layers 121 may be stacked over the semiconductor substrate 101 between the isolation layers 109 and 117. The silicon layers 121 may have N type impurities or P type impurities. The silicon layers 121 may be in monocrystalline or polycrystalline form.

By following above processes, the silicon layers 121 may be arranged over the semiconductor substrate 101 (i.e., active regions) between the isolation layers 109 and 117. In addition, a distance between adjacent silicon layers 121 may be controlled to be smaller than the minimum space that may be defined by the resolution of exposure equipment.

Referring to FIG. 1I, the upper portions of the isolation layers 109 and 117 may be further etched to expose upper sidewalls of the silicon layers 121. Here, thicknesses by which the upper portions of the isolation layers 109 and 117 are etched may be controlled to prevent an exposure of edges of the tunnel insulating layers 119.

Referring to FIG. 1J, control gates CG may be formed in a direction crossing the isolation layers 109 and 117. More specifically, a dielectric layer 123, a polysilicon layer 125, a conductive layer 127 and a hard mask layer 129 may be formed over an entire structure. Subsequently, the hard mask layer 129, the conductive layer 127, the polysilicon layer 125 and the dielectric layer 123 may be etched so that the polysilicon layer 125 and the conductive layer 127 may remain in a shape of parallel lines in the direction crossing the isolation layers 109 and 117. The dielectric layer 123 may have a stacked structure of an oxide layer, a nitride layer and an oxide layer. Another oxide layer or another nitride layer may be further formed on the top or bottom of the stacked structure. A high dielectric insulating layer with a high dielectric constant may replace the oxide layer or the nitride layer of the dielectric layer 123. The conductive layer 127 may include a metal silicide layer.

As a result, the control gate CG may have a stacked structure of the polysilicon layer 125 and the conductive layer 127. Subsequently, the silicon layers 121 exposed between the control gates CG may be removed so that silicon patterns 121A may remain under the control gate CG, and the silicon patterns 121A may become charge storage layers or floating gates FG.

As the aforementioned processes are completed, word lines WL0 to WLn, drain select lines DSL and source select lines SSL may be formed. In addition, the insulating layer 119, a floating gate FG (121), the dielectric layer 123 and the control gate CG may be stacked over the semiconductor substrate 101 between the isolation layers 109 and 117 of different depths. The stacked layers (119, 121, 123 and CG) may form memory cells. In other words, memory cells may be formed on the semiconductor substrate 101 between a pair of the isolation layers 109 and 117 of different depths.

More specifically, first trenches 107 having a first depth may be formed in the semiconductor substrate 101. Second trenches 115 having a second depth shallower than the first depth may be formed in the semiconductor substrate 101 between the first trenches 107. The isolation layers 109 and 117 having the upper portions formed above the semiconductor substrate 101 may be formed in the first trenches 107 and the second trenches 115, respectively. In addition, cell gates (WL0 to WLn) may be formed over the isolation layers 109 and 117 and the semiconductor substrate 101 in the direction crossing the isolation layers 109 and 117.

Subsequently, junctions JC may be formed at the semiconductor substrate 101 between gate lines (DSL, SSL and WL0 to WLn). After that, interlayer insulating layers (not illustrated) may be formed, and contact holes (not illustrated) may be formed in the interlayer insulating layers. Drain contact plugs DCP and source contact plug SCP may be formed in the contact holes. The drain contact plugs DCP may be formed on the junctions JC between the drain select lines DSL, and the source contact plug SCP may have a linear shape between the source select lines SSL.

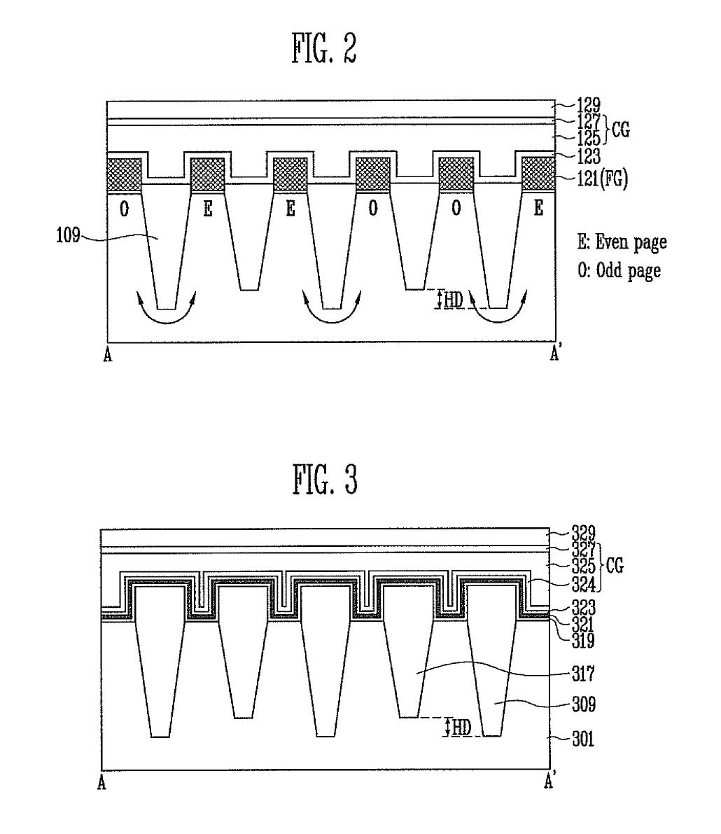

FIG. 2 is a cross-sectional view illustrating operations of a semiconductor device according to the exemplary embodiment of the present invention.

Referring to FIG. 2, on the basis of a single memory cell formed on the semiconductor substrate between isolation layers, one of the isolation layers in one direction may be deeper than the other isolation layer in the other side direction. Therefore, the amount of leakage current that occurs between memory cells at both sides of the deeper isolation layer and that flows through under the isolation layer may be reduced.

In general, memory cells in odd pages may be disposed between memory cells in even pages. More specifically, among memory cells coupled to the same word line, even memory cells may be in even pages, and odd memory cells may be in odd pages.

However, in the exemplary embodiment of the present invention, two adjacent memory cells at both sides of the second isolation layer 117 formed at the second trench 115, which has a smaller depth, may form a single memory pair. Even memory pairs may be in even pages, and odd memory pairs may be in odd pages. The above-described structural changes may be made by changing design so that a peripheral circuit may identify the even memory pairs as being in the even page and the odd memory pairs as being in the odd page, without changing a coupling structure of the memory cells.

By changing the memory cells in the even page and the odd page, the isolation layer that has a relatively greater depth may be formed between the memory cell in the even page and the memory cell in the odd page. As a result, the amount of leakage current that occurs between the memory cells (i.e., between the even page and the odd page) via the isolation layer that has a relatively greater depth between the memory cell in the even page and the memory cell in the odd page may be reduced.

FIG. 3 is a cross-sectional view illustrating the structure of a semiconductor device according to another embodiment of the present invention.

Referring to FIG. 3, according to the method described with reference to FIGS. 1A to 1G, isolation layers 309 and 317 may be formed over a semiconductor substrate 301, and hard mask spacers HM2 may be removed.

Subsequently, a tunnel insulating layer 319, a charge storage layer 321, a blocking insulating layer 323 and a protective layer 324 may be sequentially formed. Here, the charge storage layer 312 may be a layer where charges injected during a program operation are trapped. The charge storage layer 312 may include a nitride layer. The blocking insulating layer 323 may be an insulating layer that prevents the charges, which are trapped in the charge storage layer 312, from being discharged to the control gates. The blocking insulating layer 323 may be a high dielectric insulating layer with a high dielectric constant (e.g., an aluminum oxide layer).

The protective layer 324 may be formed to protect the tunnel insulating layer 319, the charge storage layer 321 and the blocking insulating layer 323 from an etch process of other layers. The protective layer 324 may be formed of a conductive material, such as a polysilicon layer doped with impurities. The protective layer 324 may be a part of the control gate CG. A total thickness of these layers (319, 321, 323 and 324) may be determined so that a difference in level caused by upper portions of the isolation layers 309 and 317 may be maintained.

The tunnel insulating layer 319, the charge storage layer 321, the blocking insulating layer 323 and the control gate CG may be stacked over the semiconductor substrate 301 between the isolation layers 309 and 317 of different depths. The stacked layers (319, 321, 323 and CG) may form memory cells. In other words, the memory cells may be formed on the semiconductor substrate 101 between a pair of the isolation layers 309 and 317 of different depths.

Subsequently, the processes described in connection with FIG. 1J may be performed. More specifically, a silicon layer 325, a conductive layer 327, and a hard mask 329 may be formed. After that, word lines WL0 to WLn, drain select lines DSL and source select lines SSL may be formed by a patterning process. Junctions JC may be formed at the semiconductor substrate 301 between gate lines (DSL, SSL and WL0 to WLn). Subsequently, interlayer insulating layers (not illustrated) may be formed, and contact holes (not illustrated) may be formed in the interlayer insulating layers. Subsequently, drain contact plugs DCP and a source contact plug SCP may be formed in the contact holes. The drain contact plugs DCP may be formed on the junctions JC between the drain select lines DSL, and the source contact plug SCP may have a linear shape between the source select lines SSL.

According to the exemplary embodiments of the present invention, fine patterns with a pattern width smaller than a resolution of exposure equipment may be formed, and at the same time, patterns may be spaced apart from one another by a shorter distance, so that an integration degree of a device may be further increased.

In addition, by forming odd isolation layers and even isolation layers of different depths, interference may be reduced during the operation of a device.

While the present invention has been described with respect to the specific embodiments, it will be apparent to those skilled in the art that various changes and modifications may be made without departing from the spirit and scope of the invention as defined in the following claims.

What is claimed is:

1. A semiconductor device, comprising:
a plurality of first trenches having a first depth formed in a semiconductor substrate;
a plurality of second trenches having a second depth formed in the semiconductor substrate, wherein the second depth is different from the first depth and the second trenches are formed between the first trenches;
a plurality of isolation layers formed at the plurality of first trenches and the plurality of second trenches, wherein the isolation layers have upper portions formed above the semiconductor substrate; and
a plurality of memory cells formed over the semiconductor substrate between the isolation layers.

2. The semiconductor device of claim 1, further comprising:
a plurality of cell gates formed over the isolation layers in a direction crossing the isolation layers, the cell gates forming word lines.

3. The semiconductor device of claim 2, wherein each of the plurality of cell gates includes a stacked structure of a dielectric layer and a control gate.

4. The semiconductor device of claim 3, wherein each of the plurality of memory cells includes a stacked structure of a tunnel insulating layer, a floating gate, a dielectric layer and a control gate.

5. The semiconductor device of claim 2, wherein each of the plurality of cell gates has a stacked structure of a tunnel insulating layer, a charge storage layer, a blocking insulating layer and a control gate.

6. The semiconductor device of claim 5, wherein the charge storage layer comprises a nitride layer.

7. The semiconductor device of claim 1, wherein the second depth is shallower than the first depth.

8. The semiconductor device of claim 1, wherein a pair of memory cells formed at both sides of an isolation layer having a shallower trench form a single memory pair.

9. A method of manufacturing a semiconductor device, the method comprising:
forming a plurality of first trenches having a first depth by etching a semiconductor substrate;
forming a plurality of first isolation layers at first trenches, wherein the first isolation layers have upper portions formed above the semiconductor substrate;
forming second trenches having a second depth different from the first depth by removing the semiconductor substrate between the first isolation layers;
forming a plurality of second isolation layers at the plurality of second trenches, wherein the second isolation layers have upper portions above the semiconductor substrate; and
forming a plurality of memory cells over the semiconductor substrate between the first and second isolation layers.

10. The method of claim 9, wherein the forming of the plurality of second trenches comprises:
forming a plurality of hard mask spacers on both sidewalls of the upper portions of the plurality of first isolation layers; and
removing the semiconductor substrate to the second depth using the hard mask spacers.

11. The method of claim 9, further comprising etching the upper portions of the plurality of first and second isolation layers before the forming of the plurality of memory cells.

12. The method of claim 9, wherein the forming of the memory cells comprises:
forming a tunnel insulating layer over the semiconductor substrate between the first and second isolation layers;
forming a floating gate over the tunnel insulating layer between the first and second isolation layers;
forming a dielectric layer over the floating gate; and
forming a control gate over the dielectric layer.

13. The method of claim 12, further comprising etching the upper portions of the plurality of first and second isolation layers to expose upper sidewalls of the floating gate after the forming of the floating gate.

14. The method of claim 9, wherein the forming of the memory cells comprises:
forming a tunnel insulating layer, a charge storage layer and a blocking insulating layer over the semiconductor substrate between the first and second isolation layers in a sequential manner; and
forming a control gate over the blocking insulating layer.

15. The method of claim 9, wherein the second depth is smaller than the first depth.
